(19) United States
(12) Patent Application Publication
(10) Pub. No.: US 2019/0287870 A1
(43) Pub. Date: Sep. 19, 2019

(54) FILLING COMPOSITION FOR SEMICONDUCTOR PACKAGE

(71) Applicant: Electronics and Telecommunications Research Institute, Daejeon (KR)

(72) Inventors: KeonSoo JANG, Daejeon (KR); Yong Sung EOM, Daejeon (KR); KWANG-SEONG CHOI, Daejeon (KR); Seok-Hwan MOON, Daejeon (KR); Hyun-cheol BAE, Sejong-si (KR)

(73) Assignee: Electronics and Telecommunications Research Institute, Daejeon (KR)

(21) Appl. No.: 16/356,615

(22) Filed: Mar. 18, 2019

(30) Foreign Application Priority Data
Mar. 19, 2018 (KR) 10-2018-0031727
Jun. 28, 2018 (KR) 10-2018-0074944

(51) Int. Cl. H01L 23/29; H01L 23/00; H01L 21/56; C08L 101/12; C08K 3/013; C08K 3/36

(52) U.S. Cl. CPC H01L 23/295; H01L 24/09; H01L 24/32; H01L 24/49; H01L 21/563; C08L 101/12; C08L 101/08; C08K 3/36; H01L 2224/73265; C08K 2201/014; C08L 2203/206; C08K 2201/005; C08K 3/013

(57) ABSTRACT

The inventive concept relates to a filling composition for a semiconductor package. The filling composition for a semiconductor package may include a resin, a curing agent, and an insulating filler. The insulating filler may include a first filler body part, a second filler body part, a polymer chain coupled to the first filler body part and the second filler body part, and supramolecules coupled to the polymer chain.

### CROSS-REFERENCE TO RELATED APPLICATIONS

This U.S. non-provisional patent application claims priority under 35 U.S.C. § 119 of Korean Patent Application Nos. 10-2018-0031727, filed on Mar. 19, 2018, and 10-2018-0074944, filed on Jun. 28, 2018, the entire contents of which are hereby incorporated by reference.

### BACKGROUND

The present disclosure herein relates to a filling composition for a semiconductor package and the manufacturing of a semiconductor package using the same.

In recent years, there has been a demand for increasing the density of a semiconductor package in accordance with the tendency in which the size of an electronic device becomes smaller and the function thereof becomes more high-tech. Accordingly, the demand for a highly integrated and miniaturized semiconductor package is increasing. Compositions for epoxy molding compound (EMC), diathecide paste (DAP), diacid film (DAF), and/or underfill may be used as a filling composition for a semiconductor package. In a manufacturing process of a semiconductor package, the filling composition is required to have thixotropy. Also, in a manufacturing process of a semiconductor package, the need to prevent the warpage of a semiconductor package has been increased. Accordingly, interests in adjusting the thermal expansion coefficient of a filling composition have been increased.

### SUMMARY

The present disclosure provides a filling composition for a semiconductor package, the composition having improved thixotropy and a low thermal expansion coefficient.

The problems of the inventive concept are not limited to the above-mentioned problem, and other problems that are not mentioned may be apparent to those skilled in the art from the following description.

An embodiment of the inventive concept provides a filling composition. According to the inventive concept, the filling composition may include a resin, a curing agent, and an insulating filler.

In an embodiment, the insulating filler may include a first filler body part, a second filler body part, a polymer chain coupled to the first filler body part and the second filler body part, and supramolecules coupled to the polymer chain.

In an embodiment, the filling composition may have a thixotropic index of 5 to 20, and a thermal expansion coefficient of 10 ppm/K to 40 ppm/K.

In an embodiment, the insulating filler may further include a first functional group coupled to the surface of the first filler body part, and a second functional group coupled to the surface of the second filler body part.

In an embodiment, the first functional group and the second functional group may include a silane-containing group, an epoxy group, a vinyl group, acid, a hydroxyl group, and/or a rubber-based group.

In an embodiment, a flux may be further included.

In an embodiment, the first filler body part and the second filler body part may include inorganic materials.

In an embodiment, the first filler body part may include a thermoplastic resin, and the second filler body part may include a thermoplastic resin.

In an embodiment, the polymer chain may include a thermoplastic polymer, the curing agent may include an anhydride group, and the resin may include a thermosetting resin.

In an embodiment, either the first filler body part or the second filler body part may have a shape of a sphere, a plate, a rod, a star, or a dendrite.

### BRIEF DESCRIPTION OF THE FIGURES

The accompanying drawings are included to provide a further understanding of the inventive concept, and are incorporated in and constitute a part of this specification. The drawings illustrate exemplary embodiments of the inventive concept and, together with the description, serve to explain principles of the inventive concept. In the drawings:

FIG. 1 schematically illustrates a filling composition for a semiconductor package;

FIG. 2A schematically illustrates an insulating filler according to an embodiment of the inventive concept;

FIG. 2B schematically illustrates an insulating filler according to another embodiment of the inventive concept;

FIG. 3A schematically illustrates an insulating filler at a first temperature;

FIG. 3B schematically illustrates an insulating filler at a second temperature;

FIG. 4A is a view schematically illustrating a packaging material according to an embodiment of the inventive concept;

FIG. 4B is a view schematically illustrating a packaging material according to another embodiment of the inventive concept;

FIG. 5A and FIG. 5B are views showing a manufacturing process of a semiconductor package according to embodiments of the inventive concept; and

FIG. 6 is a cross-sectional view illustrating a semiconductor package according to other embodiments of the inventive concept.

### DETAILED DESCRIPTION

Advantages and features of the inventive concept and methods of accomplishing the same may be understood more readily by reference to the following detailed description of exemplary embodiments and the accompanying drawings. The inventive concept may, however, be embodied in different forms and should not be construed as limited to the embodiments set forth herein. Rather, these embodiments are provided so that this disclosure will be thorough and complete, and will fully convey the scope of the inventive concept to those skilled in the art to which the inventive concept pertains. The inventive concept will only be defined by the appended claims. The same reference numerals refer to like elements throughout the specification.

Embodiments described in the present specification will be described with reference to cross-sectional views and/or plan views which are ideal illustrations of the inventive concept. In the drawings, the thickness of films and regions are exaggerated for an effective description of technical contents. Thus, the regions illustrated in the drawings have properties, and the shapes of the regions illustrated in the drawings are intended to exemplify specific shapes of regions of a device and are not intended to limit the scope of the inventive concept. Although the terms first, second, third, and the like are used in various embodiments of the inventive concept to describe various components, these components should not be limited by these terms. These terms are only used to distinguish one element from another. The embodiments described and exemplified herein also include the complementary embodiments thereof.

The terms used herein are for the purpose of describing embodiments and are not intended to be limiting of the inventive concept. In the present specification, singular forms include plural forms unless the context clearly indicates otherwise. As used herein, the terms “comprises” and/or “comprising” are intended to be inclusive of the stated elements, steps, operations and/or devices, and do not exclude the possibility of the presence or the addition of one or more other elements, steps, operations, and/or devices.

Unless otherwise defined, all the terms used herein (including technical and scientific terms) will be used in a sense that can be commonly understood to those of ordinary skill in the art to which the inventive concept pertains. In addition, the terms that are defined in a commonly used dictionary are not interpreted ideally or excessively unless specifically defined.

In the present specification, the same reference numerals may refer to the same components throughout the specification.

Hereinafter, with reference to the accompanying drawings, a filling composition according to the inventive concept and a semiconductor package manufactured using the same will be described.

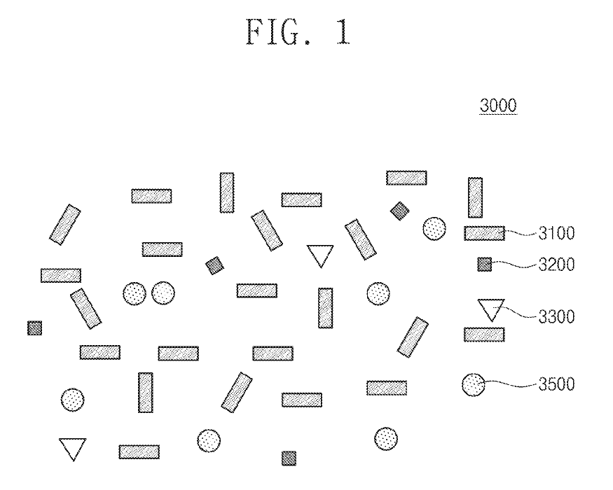

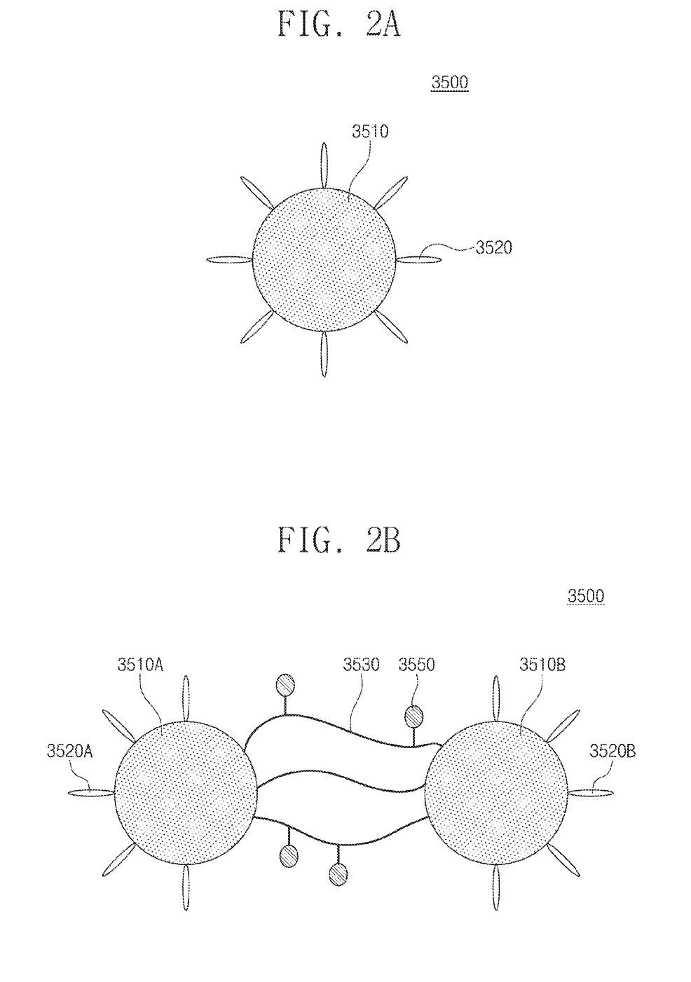

FIG. 1 schematically illustrates a filling composition for a semiconductor package. FIG. 2A schematically illustrates an insulating filler according to an embodiment of the inventive concept. FIG. 2B schematically illustrates an insulating filler according to another embodiment of the inventive concept.

Referring to FIG. 1, a filling composition 3000 may include resins 3100, an insulating filler 3500, and a curing agent 3200. The filling composition 3000 may be a filling composition for a semiconductor package. As an example, the filling composition 3000 may be transparent. The resins 3100 may be synthesized using a monomer having a molecular weight of 50-1000 g/mol. The resins 3100 may be thermosetting resins. The resins 3100 may include at least one of an epoxy resin, a phenoxy resin, a bismaleimide resin, unsaturated polyester, a urethane-based resin, a urea-based resin, a resin synthesized from a phenolic-formaldehyde-based monomer, vulcanized rubber, a melamine resin, polyimide, an epoxy novolac resin, and/or a resin synthesized from a cyanate ester monomer. As another example, the resins 3100 may include photo-curable resins.

The curing agent 3200 may be dispersed in the filling composition 3000. The curing agent 3200 may be a thermal-curing agent. The curing agent 3200 may include an anhydride group. For example, the curing agent 3200 may include any one of nadic maleic anhydride, dodecyl succinnic anhydride, maleic anhydride, succinic anhydride, metyl tetrahydro phthalic anhydride, hexahydro phthalic anhydirde, hexahydro phthalic anhydride, tetrahydro phthalic anhydride, pyromellitic dianhydride, tetrahydro phthalic anhydride, cyclohexanedicarboxylic anhydride, methyl tetrahydro phthalic anhydride, 1,2,4-benzenetricarboxylic anhydride, benzopen one-3,3′, and/or 4,4′-tetracarboxylic dianhydride. As another example, the curing agent 3200 may be a photo-curing agent. The curing agent 3200 may be 1 wt % to 70 wt % of the filling composition 3000. The equivalent ratio of the resins 3100 to the curing agent 3200 may be 1:0.1 to 1:5.

The filling composition 3000 may further include a flux 3300. The flux 3300 may function as an antioxidant. The flux 3300 may include organic acid such as formic acid, acetic acid, lactic acid, glutamic acid, oleic acid, rosolic acid, 2,2-bis(hydroxymethylene)propanoic acid, butanoic acid, propanoic acid, tannic acid, gluconic acid, pentanoic acid, hexanoic acid, hydrobromic acid, hydrochloric acid, uric acid, hydrofluoric acid, sulfuric acid, hydrochloric acid, benzglutaric acid, malic acid, phosphoric acid, oxalic acid, uranic acid, hydrochlorate, perchloric acid, gallic acid, phosphorous acid, citric acid, malonic acid, tartartic acid, phthalic acid, cinnamic acid, glutaric acid, hexanoic acid, propionic acid, stearic acid, ascorbic acid, acetylsalicylic acid, azelaic acid, benzilic acid, and/or fumaric acid. The flux 3300 may be 0.001 to 50 phr (parts per hundred rubber) of the resins 3100.

The insulating filler 3500 may be dispersed in the resins 3100. The insulating filler 3500 may be 1 wt % to 90 wt % of the filling composition 3000. Hereinafter, referring to FIG. 2A and FIG. 2B, the insulating filler 3500 will be described in more detail.

Referring to FIG. 1 and FIG. 2A, the insulating filler 3500 may include a filler body part 3510 and a functional group 3520. The filler body part 3510 may have a shape of a sphere, a plate, a rod, a star, or a dendrite. The shape of the filler body part 3510 may be modified in various ways. The filler body part 3510 may include an inorganic material or an organic material. The inorganic material may include any one of Si, Sn, Ag, Cu, In, Bi, Ni, Ma, Ba, Mn, Pd, and/or Ti. As another example, the inorganic material may be at least one of silica, Ba2SO4, alumina, clay, kaolin, talc, manganese dioxide, zinc oxide, CaCO3, TiO2, mica, wollastonite, basalt, titanium oxide, mica, wollastonite and granite. The organic material may include a thermoplastic resin. When the insulating filler 3500 includes a thermoplastic resin, the thermoplastic resin may be 20 wt % to 70 wt % of the filling composition 3000 (in FIG. 1). The thermoplastic resin may be substituted with a hydroxy group. The repeating unit of the thermoplastic resin may be 10 to 100000. As another example, the thermoplastic resin may include any one of polystyrene, polymethamethylacrylate, polyethylene terephthalate, polyisobutyl methacrylate, polyvinyl piridine, polycaprolactone, polybutadiene, polydimethylsiloxane, polyisobutylene, polyisoprene, polycarbonate, polypropylene, polyethylene, and/or polyvinyl chloride. As another example, the organic material may include polyethyelenoxide, polyvinyl alcohol, phenoxy resin, polyacrylic acid, and/or polyethyl acrylic acid. As yet another example, the organic material may include a highly heat-resistant polymer. The highly heat-resistant polymer may have a glass transition temperature (Tg) of 180° C. or higher, or a melting temperature of 300° C. or higher.

The functional group 3520 may be provided on a surface of the filler body part 3510. The functional group 3520 may be coupled to the filler body part 3510. The first functional group 3520 may be a silane-containing group, an epoxy group, a vinyl group, acid, a hydroxyl group, and/or a rubber-based group. The functional group 3520 may be a hydrophobic functional group or a hydrophilic functional group. As an example, the functional group 3520 is represented by Formula 1, and may include an epoxy group. The functional group 3520 represented by Formula 1 may be hydrophilic. As an example, the functional group 3520 is represented by Formula 2, and may include a vinyl group. The functional group 3520 represented by Formula 2 may be hydrophobic.

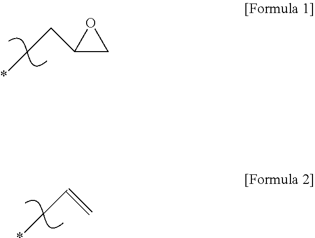

(In Formula 1 and Formula 2, * may indicate a portion coupled to the filler body part 3510).

Depending on the properties of the resins 3100 (in FIG. 1), the properties of the functional group 3520 may be determined. As an example, when the resins 3100 form a hydrophilic polymer, the functional group 3520 may be hydrophilic. When the resins 3100 exhibit hydrophobicity, the functional group 3520 may be hydrophobic. As the functional group 3520 is provided, the compatibility between the insulating filler 3500 and the resins 3100 may be improved. Accordingly, the thixotropy of the filling composition 3000 may be improved.

Referring to FIG. 2B, the insulating filler 3500 may include filler body parts 3510A and 3510B, first and second functional groups 3520A and 3520B, a polymer chain 3530, and supramolecules 3550. The filler body parts 3510A and 3510B may include a first filler body part 3510A and a second filler body part 3510B. Each of the filler body parts 3510A and 3510B may include the same material as described with reference to the filler body part 3510 of FIG. 2A. Each of the filler body parts 3510A and 3510B may have a shape of a sphere, a plate, a rod, a star, or a dendrite.

A first functional group 3520A may be provided on the first filler body part 3510A. The first functional group 3520A may be coupled to the first filler body part 3510A. A second functional group 3520B may be provided on the second filler body part 3510B. The second functional group 3520B may be coupled to the second filler body part 3510B. Each of the first functional group 3520A and the second functional group 3520B may include substantially the same group as described in the example of the functional group 3520 of FIG. 2B.

The polymer chain 3530 may be provided between the first and second filler body parts 3510A and 3510B to be coupled to the first and second filler body parts 3510A and 3510B. For example, one end of the polymer chain 3530 may be coupled to the first filler body part 3510A, and the other end of the polymer chain 3530 may be coupled to the second filler body part 3510B. The first and second filler body parts 3510A and 3510B may be connected to each other by the polymer chain 3530. The polymer chain 3530 may include a thermoplastic polymer. For example, the polymer chain 3530 may include any one of polyethyelenoxide, polyvinyl alcohol, phenoxy resin, polyacrylic acid, polyethyl acrylic acid, polystyrene, polymethamethylacrylate, polyethylene terephthalate, polyisobutyl methacrylate, polyvinyl piridine, polycaprolactone, polybutadiene, polydimethylsiloxane, polyisobutylene, polyisoprene, polycarbonate, polypropylene, polyethylene, and/or polyvinyl chloride. The repeating unit of the polymer chain 3530 may be 10 to 100000. As another example, the polymer chain 3530 may include a block copolymer.

The supramolecules 3550 may be coupled to the polymer chain 3530. The supramolecules 3550 may have any one of a self-assembly structure, an intermolecular self-assembly structure, a host-guest complex structure, and/or a mechanically interlocked molecules structure. The supramolecules 3550 may have a weight average molecular weight of approximately 30 to 10000. The supramolecules 3550 may have a functional group such as a hydroxyl group, acid, an amino group, an amide group. For example, the supramolecules 3550 may include at least one of cucurbit[10]uril, rotaxane, p-xylyene diammonium, cucurbituril, and/or UPy (2-ureido-4[1H]-pyrimidinone. Depending on temperature conditions, the intensity of intermolecular interaction between the supramolecules 3550 may vary. [0049]

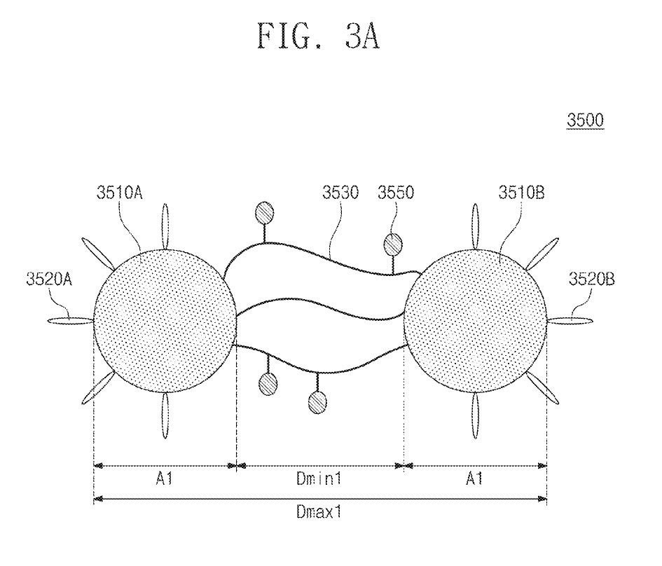

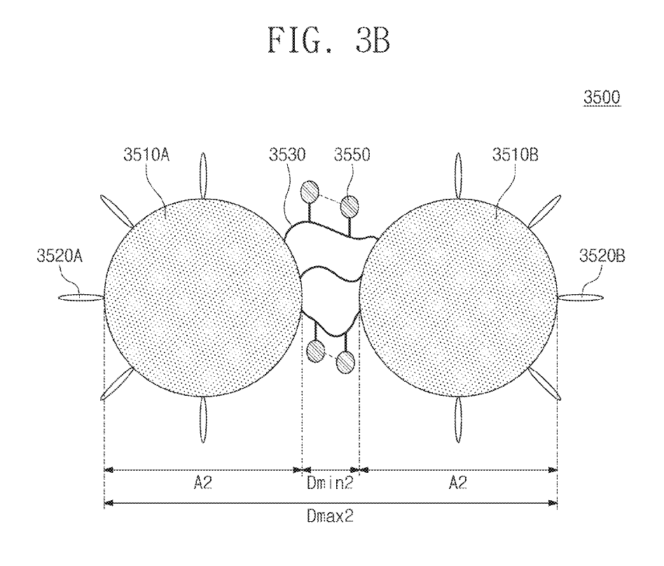

FIG. 3A schematically illustrates an insulating filler at a first temperature. FIG. 3B schematically illustrates an insulating filler at a second temperature. Hereinafter, the same descriptions as those described above will be omitted.

Referring to FIG. 3A, an insulating filler 3500 may be provided under a first temperature condition. The insulating filler 3500 may be the same as the insulating filler 3500 described with reference to FIG. 2B. For example, the insulating filler 3500 may include the filler body parts 3510A and 3510B, the first and second functional groups 3520A and 3520B, the polymer chain 3530, and the supramolecules 3550. The first temperature may be a temperature lower than the curing temperature of the filling composition 3000 of FIG. 1, or the manufacturing process temperature of a semiconductor package. As an example, the first temperature may be room temperature (for example, 25° C.). Each of the filler body parts 3510A and 3510B may have a first diameter A1. The second filler body part 3510B may be spaced apart from the first filler body part 3510A by a first minimum interval Dmin1 and a first maximum interval Dmax1. The first maximum interval Dmax1 may be substantially the same as the sum of the first minimum interval Dmin1, the first diameter A1 of the first filler body part 3510A, and the first diameter A1 of the second filler body part 3510B.

Referring to FIG. 3B, the insulating filler 3500 may be heated and provided under a second temperature condition. The second temperature may be higher than the first temperature. Under the second temperature condition, a second minimum interval Dmin2 may be provided between the first and second filler body parts 3510A and 3510B. The first and second filler body parts 3510A and 3510B may be spaced apart from each other by a second maximum interval Dmax2. The second temperature may be the curing temperature of the filling composition 3000, or the manufacturing process temperature of a semiconductor package. For example, the second temperature may be 40° C. or higher.

When the temperature increases 200b, the first and second filler body parts 3510A and 3510B may expand. Each of the first and second filler body parts 3510A and 3510B may have a second diameter A2 under the second temperature condition. The second diameter A2 may be greater than the first diameter A1. Under the second temperature condition, intermolecular interaction (e.g. hydrogen bonding) between the supramolecules 3550 may be provided as illustrated with dotted lines. By the intermolecular interaction between the supramolecules 3550, the minimum interval between the first and second filler body parts 3510A and 3510B may be reduced. Accordingly, the second minimum interval Dmin2 may be less than the first minimum interval Dmin1. The second maximum interval Dmax2 may be the same as the sum of the second minimum interval Dmin2, the second diameter A2 of the first filler body part 3510A, and the second diameter A2 of the second filler body part 3510B. Due to an increase in the second diameter A2 and a decrease in the second minimum interval Dmin2, the second maximum interval Dmax2 may be the same as or similar to the first maximum interval Dmax1.

Referring back to FIG. 3A, the insulating filler 3500 may be cooled to be provided under the first temperature condition. As the temperature decreases, the first and second filler body parts 3510A and 3510B may shrink. Accordingly, each of the first and second filler body parts 3510A and 3510B may have the first diameter A1 again. Under the first temperature condition, the intermolecular interaction between the supramolecules 3550 may be removed/reduced. Accordingly, the minimum interval between the first and second filler body parts 3510A and 3510B may be increased. The first and second filler body parts 3510A and 3510B may be spaced apart from each other by the first minimum interval Dmin1 again. The decrease in the diameter of the filler body parts 3510A and 3510B may be offset by the increase in the minimum interval of the filler body part 3510. According to embodiments, the insulating filler 3500 may have a low thermal expansion coefficient.

Referring back to FIG. 1, the filling composition 3000 may include the insulating filler 3500 of FIG. 2A. Alternately, the filling composition 3000 may include the insulating filler 3500 of FIG. 2B. The filling composition 3000 may include the insulating filler 3500, and thus, may have a low thermal expansion coefficient. For example, the filling composition 3000 may have a thermal expansion coefficient of 10 ppm/K to 40 ppm/K. The filling composition 3000 may include the insulating filler 3500, and thus, may have a high thixotropy. The thixotropy may mean that when external force is applied to a certain material, the viscosity thereof is decreased, and when external force is removed, the viscosity may be reversibly increased/restored. For example, the filling composition 3000 may have a thixotropic index of 5 to 20. The thixotropic index may be defined as the ratio of viscosity under a first external force condition to viscosity under a second external force condition of a certain material. A second external force may be greater than a first external force. For example, the thixotropic index may be evaluated by the viscosity of the filling composition 3000 at 3 rpm against the viscosity of the filling composition 3000 at 30 rpm.

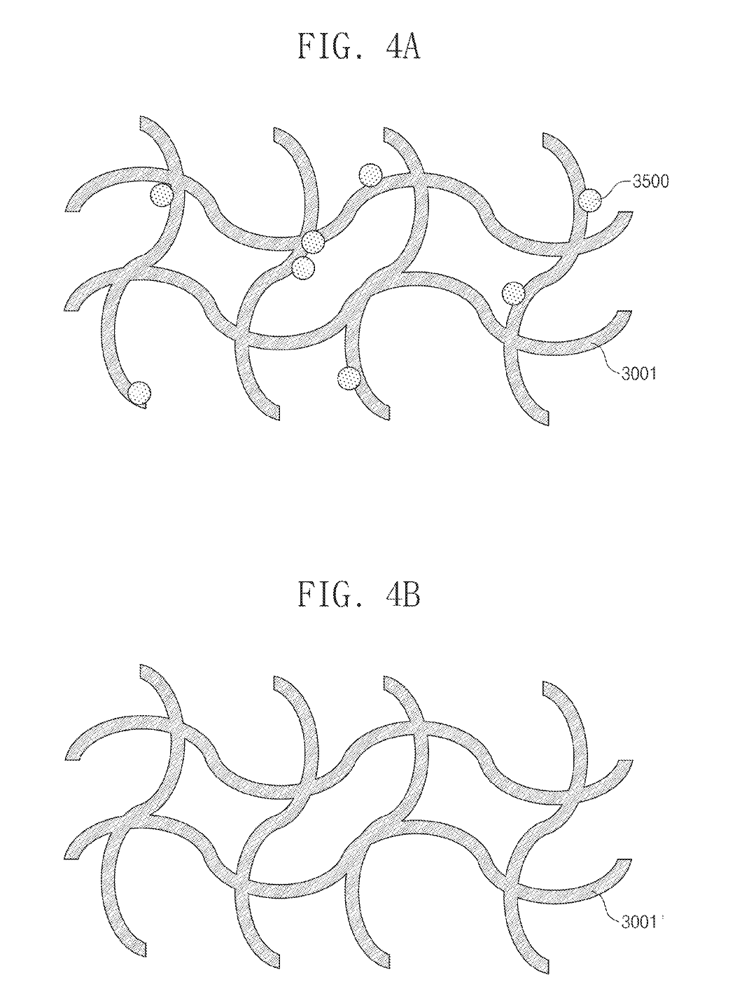

FIG. 4A is a view schematically illustrating a packaging material according to an embodiment of the inventive concept. Hereinafter, the same descriptions as those described above will be omitted.

Referring to FIG. 1 and FIG. 4A, a packaging material may include a polymer matrix 3001. The packaging material may be produced by curing the filling composition 3000. The curing of the filling composition 3000 may refer to the curing of the resins 3100. The curing of the filling composition 3000 may be performed by thermal-curing or photo-curing. The thermal-curing may be performed at 100° C. to 300° C. The thermal-curing may be performed by using a reflow oven or laser. The laser may have an infrared wavelength, but is not limited thereto. During the curing process, a crosslinking reaction of the resins 3100 and the curing agent 3200 may proceed to form the polymer matrix 3001. The insulating filler 3500 does not participate in the crosslinking reaction, and thus, may be dispersed in the polymer matrix 3001. The insulating filler 3500 may be coupled to the polymer matrix 3001 through the functional groups 3520 of FIG. 2A, 3520A or 3520B of FIG. 2B. The insulating filler 3500 may be the same as described with reference to FIG. 2A or FIG. 2B. The flux 3300 may be removed. The packing material may have insulation properties.

FIG. 4B is a view schematically illustrating a packaging material according to another embodiment of the inventive concept. Hereinafter, the same descriptions as those described above will be omitted.

Referring to FIG. 1 and FIG. 4B, a packaging material may be produced by curing the filling composition 3000. In an embodiment of the inventive concept, the packing material may include a polymer matrix 3001′. The curing of the filling composition 3000 may be performed by the same method as described with reference to FIG. 4A. When the insulating filler 3500 includes an organic material, the insulating filler 3500 may participate in the formation of crosslinking bonding. Accordingly, the polymer matrix 3001′ may be formed by the crosslinking bonding of the resins 3100, the insulating filler 3500, and the curing agent 3200. The flux 3300 may be removed. The packing material may have insulation properties.

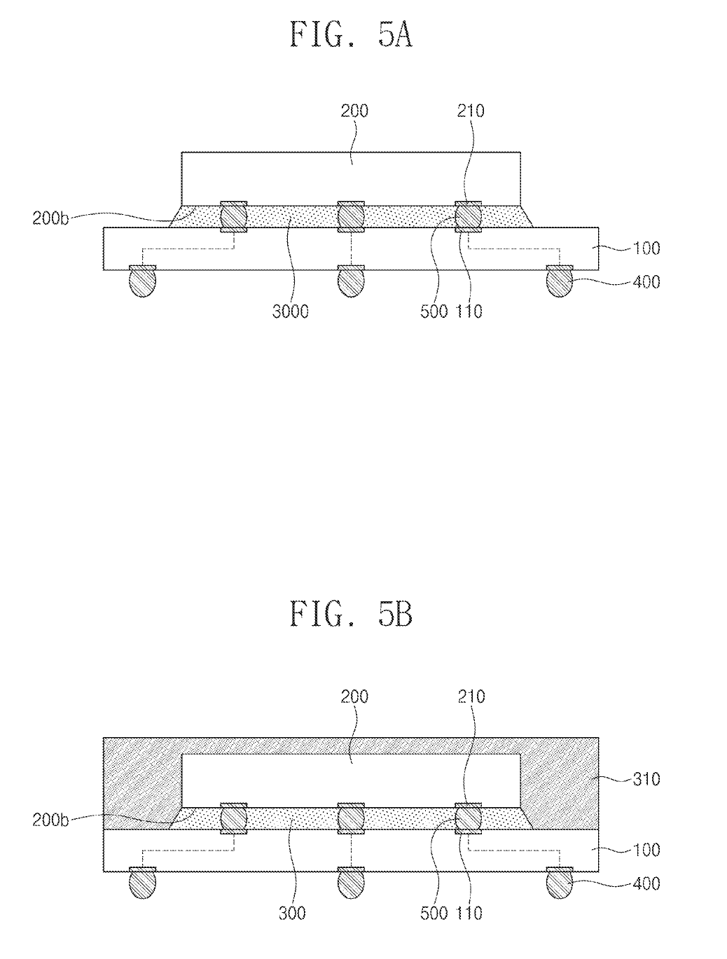

FIG. 5A and FIG. 5B are views showing a manufacturing process of a semiconductor package according to embodiments of the inventive concept. Hereinafter, the same descriptions as those described above will be omitted.

Referring to FIG. 1 and FIG. 5A, a semiconductor chip 200 may be mounted on a substrate 100. For example, a printed circuit board PCB may be used as the substrate 100. An external terminal 400 may be provided on a lower surface 200B of the substrate 100. The external terminal 400 may be electrically connected to an external device (not shown). The external terminal 400 may have a shape of a solder ball and include metal. A substrate pad 110 may be provided on an upper surface of the substrate 100. The substrate pad 110 may include metal. The substrate pad 110 may be electrically connected to the external terminal 400 through a wiring. In the following drawings, dotted lines in the substrate 100 schematically show the wiring.

The semiconductor chip 200 may be mounted on the substrate 100 in a flip-chip manner. For example, a chip pad 210 may be disposed on the lower surface 200B of the semiconductor chip 200. A connection terminal 500 may include at least one of shoulder, bump, and filler. The connection terminal 500 may be interposed between the substrate pad 110 and the chip pad 210. The semiconductor chip 200 may be electrically connected to the substrate 100 through the connection terminal 500. The connection terminal 500 may include a conductive material such as silver, tin, bismuth, and/or copper. On a sidewall of the connection terminal 500, an oxide film (not shown) may be formed. The oxide film may be formed by natural oxidation of the connection terminal 500.

The filling composition 3000 may be filled in a gap between the substrate 100 and the semiconductor chip 200. At this time, the filling composition 3000 described with reference to FIG. 1 may be used. The filling composition 300 may have thixotropy. In the process of injecting or applying the filling composition 3000 in the gap, external force may be applied to the filling composition 3000. Since the filling composition 3000 has thixotropy, when the external force is applied, the viscosity thereof may be reduced. Accordingly, the filling composition 3000 may easily fill the gap between the substrate 100 and the semiconductor chip 200. When the application of the filling composition 3000 is complete, the external force applied to the filling composition 3000 may be removed or reduced. In this case, the viscosity of the filling composition 3000 increases, so that it may be difficult for the filling composition 3000 to flow. The filling composition 3000 may maintain the state of filling the gap. The filling composition 3000 may surround the sidewall of the connection terminal 500. The filling composition 3000 may further include the flux 3300, and thus remove the oxide film. The flux 3300 may be removed by being reacted with the oxide film. Accordingly, the reliability of a semiconductor package may be improved.

Referring to FIG. 1 and FIG. 5B, the filling composition 3000 may be cured, and thus form an underfill film 300. The underfill film 300 fills the gap between the substrate 100 and the semiconductor chip 200, and may seal the connection terminal 500. According to embodiments of the inventive concept, since the filling composition 3000 maintains the state of filling the gap, the underfill film 300 may be easily formed. As an example, the curing of the filling composition 3000 ma proceed by the method described in the manufacturing of a packaging material of FIG. 4A. The underfill film 300 may include the polymer matrix 3001′ and the insulating filler 3500 as shown in FIG. 5A. As another example, the underfill film 300 may include the polymer matrix 3001′ as shown in FIG. 5B. The flux 3300 inside the filling composition 3000 may be removed by the reaction with the oxide film described with reference to FIG. 5A. The flux 3300 may not remain inside the underfill film 300.

Since the filling composition 3000 has a low thermal expansion coefficient, dimensional stability may be improved in a manufacturing process of a semiconductor package. For example, in a manufacturing process of a semiconductor package, the warpage of the substrate 100 or the semiconductor chip 200 may be prevented. The manufacturing process of a semiconductor package may include a process of curing the filling composition 3000.

A molding film 310 may be formed on the substrate 100 to cover the semiconductor chip 200. The molding film 310 may include an insulating material. For example, the molding film 310 may include an insulating polymer such as an epoxy-based molding compound. As another example, the molding film 310 may be produced using the filling composition 3000 described with reference to FIG. 1. For example, the filling composition 3000 of FIG. 1 may be applied on the substrate 100 and the semiconductor chip 200 to form a preliminary molding film (not shown). By curing the preliminary molding film, the molding film 310 may be formed. The curing of the preliminary molding film may be performed by photo-curing or thermal-curing. Since the filling composition 3000 has thixotropy, the molding film 310 may be easily formed. Since the filling composition 3000 has a low thermal expansion coefficient, in the formation process of the molding film 310, the warpage of the substrate 100 or the semiconductor chip 200 may be prevented. The molding film 310 may include a packaging material as shown in FIG. 4A or FIG. 4B. The manufacturing of a semiconductor package may be completed by the manufacturing example described so far.

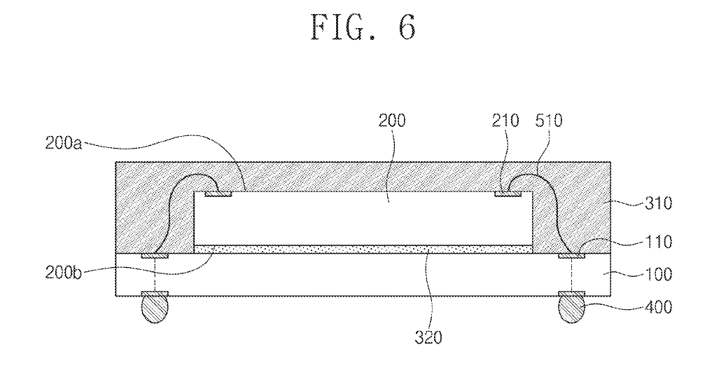

FIG. 6 is a cross-sectional view illustrating a semiconductor package according to other embodiments of the inventive concept. Hereinafter, the same descriptions as those described above will be omitted.

Referring to FIG. 6, a semiconductor package may include a substrate 100, a semiconductor chip 200, an adhesive film 320, and a molding film 310. The substrate 100 and the semiconductor chip 200 may be substantially the same as those described with reference to FIG. 5A and FIG. 5B. However, a chip pad 210 may be provided on an upper surface 200A of the semiconductor chip 200. The lower surface 200B of the semiconductor chip 200 may be directed to the substrate 100. A bonding wire 510 may be provided on the upper surface 200A of the semiconductor chip 200. The bonding wire 510 may be connected to the chip pad 210 and a substrate pad 110. The semiconductor chip 200 may be electrically connected to the substrate 100 through the bonding wire 510.

The adhesive film 320 may be interposed between the substrate 100 and the semiconductor chip 200. The semiconductor chip 200 may be fixed to the substrate 100 by the adhesive film 320. The adhesive film 320 may be produced using the filling composition 3000 of FIG. 1. Since the filling composition 3000 has thixotropy, the adhesive film 320 may be easily formed. Since the filling composition 3000 has a low thermal expansion coefficient, in the formation process of the adhesive film 320, the warpage of the substrate 100 or the semiconductor chip 200 may be prevented. The adhesive film 320 may include a packaging material as shown in FIG. 4A or FIG. 4B. The adhesive film 320 may have insulating properties.

A molding film 310 may be formed on the substrate 100 to cover the semiconductor chip 200 and the bonding wire 510. The molding film 310 may include an insulating polymer such as an epoxy-based molding compound. As another example, the molding film 310 may be produced using the filling composition 3000 described with reference to FIG. 1.

Hereinafter, the preparation of filling compositions according to experimental examples of the inventive concept will be described.

### EXPERIMENTAL EXAMPLE 1

Silica synthesized in a dendrite shape and having a size of 10 nm to 5 mm is prepared as an insulating filler. The insulating filler may be added in an amount of 1 wt % to 90 wt %. At room temperature (25° C.), maleimide (resins) and succinic anhydride (thermal-curing agent) are mixed in a stoichiometric ratio of 1:0.1-1:5.0. A flux is added to the mixed solution so as to be 0.001-50 phr of the maleimide. An insulating filler is added thereto to prepare a filling composition. At this time, the content ratio of the insulating filler is 1 wt % to 90 wt %.

The curing process is preformed using a reflow oven.

### EXPERIMENTAL EXAMPLE 2

A plate-shaped BaSO₄ having a diameter of 100 nm to 5 mm and a thickness of 10 nm to 0.1 mm is prepared as a filler body part. An epoxy functional group is substituted on a surface of the filler body part to prepare an insulating filler. At room temperature, an epoxy resin and maleic anhydride are mixed in a stoichiometric ratio of 1:0.1-1:5.0. A flux of 0.001-50 phr is added to the mixed solution. An insulating filler is added thereto to prepare a filling composition. At this time, the content ratio of the insulating filler is 1 wt % to 90 wt %.

Using the filling composition, an underfill film of a semiconductor package is prepared. At this time, the mounting of a semiconductor chip is performed in a flip chip bonding manner by thermal compression bonding.

### EXPERIMENTAL EXAMPLE 3

A rod-shaped polymer having a length of 100 nm to 10 mm and a diameter of 10 nm to 1 mm is prepared as a filler body part. A vinyl-based functional group is substituted on a surface of the filler body part to prepare an insulating filler. At room temperature, a phenolic resin and aldehyde are mixed in a stoichiometric ratio of 1:0.1-1:5.0. A flux of 0.001-50 phr is added to the mixed solution. An insulating filler is added thereto to prepare a filling composition. At this time, the content ratio of the insulating filler is 1 wt % to 90 wt %.

The curing process is preformed using laser.

### EXPERIMENTAL EXAMPLE 4

A sphere-shaped polymer having a diameter of 10 nm to 10 mm is prepared as filler body parts. A nano-sized polymer chain supramolecules of which are substituted is prepared. The polymer chain is coupled to the filler body parts to prepare an insulating filler. At room temperature, bisphenol F-based epoxy polymer and phthalic anhydrie are mixed in a stoichiometric ratio of 1:0.1-1:5.0 and a flux of 0.0001-50 phr is added thereto. An insulating filler is added thereto to prepare a filling composition. At this time, the content ratio of the insulating filler is 1 wt % to 90 wt %.

The curing process is preformed using laser.

According to embodiments of the inventive concept, a filling composition may include an insulating filler. The insulating filler may include a functional group or a supramolecule. Accordingly, the filling composition may have improved thixotropy and a low thermal expansion coefficient.

The effects of the inventive concept are not limited to the above-mentioned effects, and other effects that are not mentioned may be apparent to those skilled in the art from the following description of claims.

Although the preferred embodiments of the inventive concept have been shown and described, the inventive concept is not limited to the specific embodiments described above. Various changes in form and details may be made therein by those skilled in the art without departing from the spirit and scope of the present invention as defined by the appended claims, and these modifications are not to be individually understood from the technical spirit or scope of the inventive concept.

What is claimed is:

1. A filling composition for a semiconductor package, the composition comprising:
a resin;
a curing agent; and
an insulating filler, wherein
the insulating filler includes:
a first filler body part;
a second filler body part;
a polymer chain coupled to the first filler body part and the second filler body part; and
supramolecules coupled to the polymer chain.

2. The filling composition of claim 1, the filling composition has a thixotropic index of 5 to 20, and a thermal expansion coefficient of 10 ppm/K to 40 ppm/K.

3. The filling composition of claim 1, wherein the insulating filler further comprises:
a first functional group coupled to a surface of the first filler body part; and
a second functional group coupled to a surface of the second filler body part.

4. The filling composition of claim 3, wherein the first functional group and the second functional group comprise a silane-containing group, an epoxy group, a vinyl group, acid, a hydroxyl group, and/or a rubber-based group.

5. The filling composition of claim 1, further comprising a flux.

6. The filling composition of claim 1, wherein the first filler body part and the second filler body part comprise inorganic materials.

7. The filling composition of claim 1, wherein the first filler body part comprises a thermoplastic resin, and the second filler body part comprises a thermoplastic resin.

8. The filling composition of claim 1, wherein the polymer chain comprises a thermoplastic polymer, the curing agent comprises an anhydride group, and the resin comprises a thermosetting resin.

9. The filling composition of claim 1, wherein either the first filler body part or the second filler body part has a shape of a sphere, a plate, a rod, a star, or a dendrite.
